(19) United States
(12) Patent Application Publication
(10) Pub. No.: US 2007/0006913 A1
(43) Pub. Date: Jan. 11, 2007

(54) Improved Photovoltaic Device and Module

(75) Inventors: Ralph Romero, Williamsburg, VA (US); David E. Carlson, Williamsburg, VA (US); Frank S. Willing, Williamsburg, VA (US); David H. Meakin, Quinton, VA (US)

Correspondence Address: CAROL WILSON;BP AMERICA INC., MAIL CODE 5 EAST, 4101 WINFIELD ROAD, WARRENVILLE, IL, 60555, US

(73) Assignee: BP CORPORATION NORTH AMERICA INC., Warrenville, IL (US)

(21) Appl. No.: 11/530,641

(22) Filed: Sep. 11, 2006

Related U.S. Application Data
(63) Continuation of application No. 10/654,174, filed on Sep. 3, 2003.
(60) Provisional application No. 60/407,908, filed on Sep. 4, 2002.

(51) Int. Cl. H01L 31/00

(52) U.S. Cl. 136/258

(57) ABSTRACT

A thin-film photovoltaic device comprising a hard conductive transparent oxide front contact layer, and photovoltaic modules comprising such devices. The photovoltaic modules of this invention comprising hard conductive transparent front contact layers have excellent resistance to corrosion.

This application claims the benefit of U.S. Provisional Application No. 60/407,908, having a filing date of Sep. 4, 2002.

### BACKGROUND OF THE INVENTION

This invention relates to new photovoltaic devices. This invention relates to new photovoltaic devices that are thin-film photovoltaic devices. More particularly, this invention relates to thin film photovoltaic devices in the form of thin-film photovoltaic modules that have excellent resistance to corrosion.

Photovoltaic devices convert light energy, especially solar energy, into electrical energy. Photovoltaically generated electrical energy can be used for all the same purposes of electricity generated by batteries or electricity obtained from established electrical power grids, but is a renewable form of electrical energy. Sunlight is the only requirement to produce electricity using a photovoltaic device.

One type of photovoltaic device is known as a thin film device. These devices are suitably manufactured by depositing a thin, photovoltaically active layer or layers onto a suitable plate or sheet of substrate material such as glass, plastic or metal. The photovoltaically active element is in the form of a thin film. This class of photovoltaic devices is referred to herein as thin film photovoltaic devices and the photovoltaic elements contained therein as thin film photovoltaic elements. Although the present invention is not limited to such, two common types of thin film photovoltaic devices have as their photovoltaic element thin amorphous silicon films or cadmium sulfide/cadmium telluride (CdS/CdTe) films. Other types of thin film photovoltaic devices are, for example copper indium diselenide (CIS) with or without a gallium (CIGS) or a sulfur (CISS) component, or gallium arsenide photovoltaic elements. Methods for manufacturing such thin film photovoltaic elements are well known to those of skill in the art of making photovoltaic devices. After the thin film is deposited on a substrate, a second substrate is generally sandwiched to the first substrate with the thin film photovoltaic element positioned between the substrates. Generally, a polymeric material, such as poly ethyl vinyl acetate (EVA), is placed between the substrates and the substrates are heated and pressed together to form the photovoltaic module containing the photovoltaic element or elements sandwiched between the substrates. The EVA seals the substrate plates together thereby providing structural strength for the sealed module.

Most photovoltaic modules are used in an outdoor environment to maximize exposure to the sun. Being outdoors at all times, the module is exposed to air and to moisture in the form of rain, humid air, fog and, depending on the location, snow, as well as other forms of atmospheric precipitation. Thin film-type photovoltaic modules can corrode in such environment. The corrosion affects the appearance of the module and in time may affect the performance of the module as well. Therefore, there is a strong need in the art for a thin film module that does not corrode or that corrodes only very slightly with time when exposed to the environment. The present invention provides such new, corrosion resistant thin film photovoltaic devises and modules.

### SUMMARY OF THE INVENTION

This invention is a thin-film photovoltaic device comprising a hard conductive transparent oxide front contact layer. Preferably, such photovoltaic device is in the form of a module. Preferably the photovoltaic device or module of this invention comprises a photovoltaic element comprising amorphous silicon or cadmium telluride/cadmium sulfide. As used herein a module is a collection of individual photovoltaic elements generally electrically connected to produce a module having a desired voltage.

### BRIEF DESCRIPTION OF THE FIGURES

FIG. 1 is a graph showing the exceptional and unexpected corrosion resistance of modules of this invention comprising hard front contact layers.

### DETAILED DESCRIPTION OF THE INVENTION

This invention is a photovoltaic device and a photovoltaic module. The photovoltaic deices and modules of this invention are useful for generating electricity photovoltaically and are highly resistant to corrosion formation.

The photovoltaic devices and photovoltaic module of this invention comprises a first substrate and a second substrate and at least one photovoltaic device positioned between the substrates. The substrates are spaced apart from each other and sealed to one another.

The susbstrates used to form the photovoltaic modules of this invention can be, for example, glass, such as float glass, soda-lime glass or a low iron glass, a durable, or strong polymeric material such as a polyimide. A light transmissive substrate provides for light entering the module to interact with the photovoltaic element or elements located between the substrates. Glass, particularly a high transparent or transmissive glass, is preferred for the side of the module receiving the light to be converted into electricity, e.g., the sun's rays.

The photovoltaic element whether it is a thin film amorphous silicon photovoltaic element, a thin film CdS/CdTe photovoltaic element, a thin film copper indium diselenide (CIS) with or without a gallium (CIGS) or a sulfur (CISS) component, or a thin film gallium arsenide photovoltaic element or some other photovoltaic element, is positioned between the substrates in the module of this invention.

In the photovoltaic modules of this invention it is preferred to have an encapsulant such as EVA and the like, placed between the substrates and covering the photovoltaic elements. An encapsulant provides for the protection of the photovoltaic element from, for example, the environment, and adds structural strength to the module by adhering the substrates together to form the module.

Methods for making photovoltaic elements useful in the module of this invention are known to those of skill in the art. For example, methods for manufacturing amorphous silicon thin film photovoltaic elements useful in the sealed module of this invention are described in, for example, U.S. Pat. No. 4,064,521, U.S. Pat. No. 4,292,092, UK Patent Application 9916531.8 (Publication No. 2339963), Feb. 9, 2000, U.S. Pat. No. 5,593,901, U.S. Pat. No. 4,783,421, U.S. Pat. No. 6,121,541, all of which are incorporated by reference herein. Also incorporated by reference is U.S. patent application Ser. No. 09/891,752. filed on Jun. 26, 2001.

Methods for making CdS/CdTe photovoltaic elements and photovoltaic devices are described in N. R. Pavaskar, et al., J. Electrochemical Soc. 124 (1967) p. 743; 1. Kaur, et al., J. Electrochem Soc. 127 (19181) p. 943; Panicker, et al., “Cathodic Deposition of CdTe from Aqueous Electrolytes,” J. Electrochem Soc. 125, No. 4, 1978, pp. 556-572, U.S. Pat. No. 4,400,244; EP Patent 244963; U.S. Pat. No. 4,548,681, EP Patent 0538041; U.S. Pat. No. 4,388,483; U.S. Pat. No. 4,735,662; U.S. Pat. No. 4,456,630; U.S. Pat. No. 5,472,910; U.S. Pat. No. 4,243,432; U.S. Pat. No. 4,383,022, “Large Area Appolllo® Module Performance and Reliability ” 28^{th} IEEE Photovoltaic Specialists Conference, Anchorage, Alaska, Sep. 2000; all of which are incorporated by reference herin.

The thin-film photovoltaic devices and modules made therefrom of this invention have a front, thin-film contact of conductive transparent oxide (“CTO”) on the substrate made from one or more of tin oxide, zinc oxide, indium-tin oxide and the like. For example, when the photovoltaic device is an amorphous silicon or cadmium telluride/cadmium sulfide type of photovoltaic device, the amorphous silicon or cadmium telluride/cadmium sulfide layers are sandwiched between the front contact layer and a rear contact layer, typically comprising a thin film of one or more metals such as aluminum. The transparent, conductive CTO layer permits the passage of light so that the light can enter and interact with the photovoltaically active elements of the thin film photovoltaic device, and also serve as an electrical conductor or contact necessary for the operation of the thin film photovoltaic device. Generally, the CTO layer is less that about 10,000, and preferably about 2000 to about 8000 angstroms in thickness and can be applied by one or more methods known to those of skill in the art. The front contact can also comprise a silicon dioxide layer between the substrate, such as a glass substrate, and the CTO layer.

It is also possible, and is preferable, to obtain glass substrates having a front contact layer deposited thereon from commercial glass manufacturers such as AFG Industries, Inc. Such glass substrates purchased from glass suppliers are a convenient for manufacturing thin film photovoltaic devices and modules of this intention.

We determined that the corrosion resistance of photovoltaic modules devices and modules is significantly improved using a substrate having a hard CTO layer, preferably where the front contact CTO layer comprises tin oxide, and more preferably where the CTO layer is tin oxide.

The hardness of a CTO layer in accordance with is invention can be measured according to the following test procedure:

A piece of CTO coated glass to be measured is mounted flat on a fixture underneath the Taber Model 5700 Linear Abraser. The coated glass has a 25 mm wide and about 6 inch long strip of the CTO layer to be measured. Wires are soldered to the CTO layer about 2 inches apart. The abraser head is passed back and forth in one location across the surface of the CTO coating between the wires and at a direction perpendicular to the length of the strip. The number of passes of the abraser head, as counted by the Taber unit, corresponds to the hardness of the CTO coating. The endpoint of the measurement is determined by measuring the resistance across the abraded section using the soldered wires. When the resistance exceeds 20 megohms, the CTO coating is considered to be completely removed and the Number of Taber Abraser passes to achieve such resistance when starting with a 6000 angstrom thickness CTO layer is the hardness of the CTO layer in accordance with this invention using the Taber model 5700 Linear Abraser settings as follows:
1) Eraser tip: CS-10
2) Load on abrasive head: 850 grams
3) Stoke length: 38 mm
   Stoke rate: 60 cycles/minute

Photovoltaic device photovoltaic modules of this invention comprising a CTO layer, preferably comprising tin oxide, where the CTO of the layer of the photovoltaic module of this invention has a hardness of at least about 200, preferably at least about 400, more preferably at least about 500, at least about 600, and most preferably of at least about 700 Number of Taber Abraser passes, measured when using a CTO layer that is 6000 angstroms thick, have unexpectedly and surpising resistance to corrosion. Preferably, the photovoltaic devices and photovoltaic modules of this invention comprise thin films of amorphous silicon or cadmium telluride/cadmium sulfide. This invention is also a method of manufacturing a photovoltaic device and photovoltaic modules using a front contact CTO layer preferably comprising tin oxide, where the CTO has a hardness of at least about 200, preferably at least about 400, more preferably at least about 500, at least about 600, and most preferably of at least about 700 Number of Taber Abraser passes measured when using a CTO layer that is 6000 angstroms thick, and preferably where photovoltaic devices and photovoltaic modules comprise thin films of amorphous silicon or cadmium telluride/cadmium sulfide. The hardness can be up to about 900 Number of Taber Abraser passes or more.

### EXAMPLES

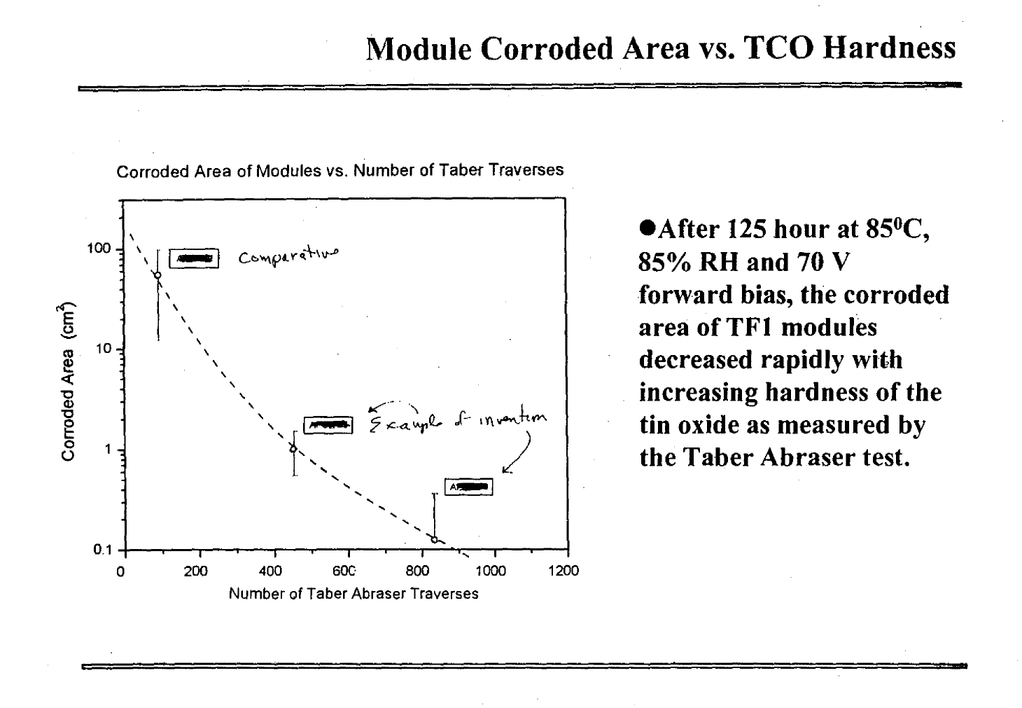

FIG. 1 shows the graph of the area of corrosion as a function of CTO, in this case, tin oxide, front contact hardness. The graph shows the excellent corrosion resistance of the module using the hard, front contact CTO layers in accordance with this invention. In the examples plotted in FIG. 1, the corrosion was accelerated by exposing the module to air at 85° C. at 85% relative humidity after 125 hours and then measuring the area of the module in square centimeters that was corroded.

U.S. Provisional Application 60/348,235 is incorporated herein by reference. U.S. Provisional Application No. 60/407,908 having a filing date of Sep. 4, 2002, is incorporated herein by reference.

Having described the invention, that which is claimed is:

1. A photovoltaic device comprising a first substrate, a second substrate, at least one photovoltaic element positioned between the first and second substrates, a front CTO contact positioned between the first substrate and the photovoltaic element where the front CTO contact comprises a CTO having a hardness of at least about 200 Number of Taber Abraser passes, measured when using a CTO layer that is 6000 angstroms thick.

2. The photovoltaic device of claim 1 wherein front CTO contact comprises a CTO having a hardness of at least about 300 Number of Taber Abraser passes measured when using a CTO layer that is 6000 angstroms thick.

3. The photovoltaic device of claim 1 wherein front CTO contact comprises a CTO having a hardness of at least about 400 Number of Taber Abraser passes measured when using a CTO layer that is 6000 angstroms thick.

4. The photovoltaic device of claim 1 wherein front CTO contact comprises a CTO having a hardness of at least about 500 Number of Taber Abraser passes measured when using a CTO layer that is 6000 angstroms thick.

5. The photovoltaic device of claim 1 wherein front CTO contact comprises a CTO having a hardness of at least about 600 Number of Taber Abraser passes measured when using a CTO layer that is 6000 angstroms thick.

6. The photovoltaic device of claim 1 wherein front CTO contact comprises a CTO having a hardness of at least about 700 Number of Taber Abraser passes measured when using a CTO layer that is 6000 angstroms thick.

7. A photovoltaic module comprising the photovoltaic device of claim 1.

8. A thin film photovoltaic device comprising a front CTO contact where the CTO has a hardness of at least about 300 Number of Taber Abraser passes measured when using a CTO layer that is 6000 angstroms thick.

9. A photovoltaic module comprising the photovoltaic device of claim 8.

10. The photovoltaic device of claim 1 wherein the CTO contact comprises tin oxide.

11. The photovoltaic device of claim 1 wherein the photovoltaic device comprises amorphous silicon.

12. The photovoltaic device of claim 1 wherein the CTO contact has a thickness of about 2000 to about 8000 angstroms.

13. A method of making a photovoltaic device comprising using a front contact CTO layer having a hardness of at least about 200 Number of Taber Abraser passes measured when using a CTO layer that is 6000 angstroms thick.

14. The method of claim 13 wherein the CTO layer has a hardness of at least about 200 Number of Taber Abraser passes measured when using a CTO layer that is 6000 angstroms thick.

15. The method of claim 13 wherein the CTO layer has a hardness of at least about 400 Number of Taber Abraser passes measured when using a CTO layer that is 6000 angstroms thick.

16. The method of claim 13 wherein the CTO layer has a hardness of at least about 500 Number of Taber Abraser passes measured when using a CTO layer that is 6000 angstroms thick.

17. The method of claim 13 wherein the CTO layer has a hardness of at least about 600 Number of Taber Abraser passes measured when using a CTO layer that is 6000 angstroms thick.

18. The method of claim 13 wherein the CTO layer has a hardness of at least about 700 Number of Taber Abraser passes measured when using a CTO layer that is 6000 angstroms thick.

19. The method claim 13 wherein the CTO contact comprises tin oxide.

20. The method of claim 13 wherein the CTO contact is about 2000 to about 8000 angstroms thick.
